(19) United States
(12) Patent Application Publication
(10) Pub. No.: US 2024/0318980 A1
(43) Pub. Date: Sep. 26, 2024

(54) SENSOR MODULE

(71) Applicant: SEIKO EPSON CORPORATION, Tokyo (JP)

(72) Inventor: Masayoshi TODOROKIHARA, Suwa (JP)

(21) Appl. No.: 18/611,954

(22) Filed: Mar. 21, 2024

(30) Foreign Application Priority Data
Mar. 22, 2023 (JP) 2023-045057

(51) Int. Cl. G01D 1/14; G01D 21/02

(52) U.S. Cl. CPC G01D 1/14; G01D 21/02

(57) ABSTRACT

A sensor module includes: a reference period signal generation unit configured to output a reference period signal; a first count unit configured to generate, in synchronization with one of a first measured signal output by a first physical quantity sensor and the reference period signal, a first count value of a time event of the other of the first measured signal and the reference period signal; a second count unit configured to generate, in synchronization with one of a second measured signal output by a second physical quantity sensor and the reference period signal, a second count value of a time event of the other of the second measured signal and the reference period signal; a first filter configured to receive the first count value and output a third count value; a second filter configured to receive the second count value and output a fourth count value; and a filter unit configured to output a measurement value based on a difference between the third count value and the fourth count value.

The present application is based on, and claims priority from JP Application Serial Number 2023-045057, filed Mar. 22, 2023, the disclosure of which is hereby incorporated by reference herein in its entirety.

### BACKGROUND

### 1. Technical Field

The present disclosure relates to a sensor module.

### 2. Related Art

WO2015/145489A discloses an acceleration sensor including a first acceleration sensor, a second acceleration sensor whose detection axis direction is opposite to that of the first acceleration sensor, and a differential value detection unit that obtains a differential value between a detection value from the first acceleration sensor and a detection value from the second acceleration sensor. According to the technology disclosed in WO2015/145489A, since the detected acceleration can be increased while removing in-phase electrical noise, a highly accurate acceleration sensor can be provided.

WO2015/145489A is an example of the related art.

In the acceleration sensor disclosed in WO2015/145489A, although the in-phase noise can be removed, it is difficult to reduce noise that is not in-phase such as noise specific to the first acceleration sensor and the second acceleration sensor.

### SUMMARY

A sensor module according to an aspect of the present disclosure including:
a first physical quantity sensor configured to detect a physical quantity using a first axis as a detection axis and output a first measured signal whose frequency changes according to a magnitude of the physical quantity;
a second physical quantity sensor configured to detect a physical quantity using a second axis in a direction opposite to the first axis as a detection axis and output a second measured signal whose frequency changes according to a magnitude of the physical quantity;
a reference period signal generation unit configured to output a reference period signal;
a first count unit configured to count, in synchronization with one of the first measured signal and the reference period signal, a time event of the other of the first measured signal and the reference period signal to generate a first count value;
a second count unit configured to count, in synchronization with one of the second measured signal and the reference period signal, a time event of the other of the second measured signal and the reference period signal to generate a second count value;
a first filter configured to receive the first count value and output a third count value;
a second filter configured to receive the second count value and output a fourth count value; and
a filter unit configured to output a measurement value based on a difference between the third count value and the fourth count value.

### BRIEF DESCRIPTION OF THE DRAWINGS

FIG. 1 is a block diagram illustrating a configuration of a sensor module according to a first embodiment.

FIG. 2 is a timing chart diagram illustrating an example of an operation of the sensor module.

FIG. 3 is a diagram illustrating an example of a configuration of a first count unit or a second count unit.

FIG. 4 is a diagram illustrating an example of a configuration of a time digital value generation unit.

FIG. 5 is a diagram illustrating an example of a configuration of a combined output value generation unit.

FIG. 6 is a diagram illustrating an example of a configuration of an oscillation unit.

FIG. 7 is a timing chart diagram illustrating an example of operations of the time digital value generation unit and the combined output value generation unit according to the first embodiment.

FIG. 8 is a timing chart diagram illustrating an example of the operations of the time digital value generation unit and the combined output value generation unit according to the first embodiment.

FIG. 9 is a block diagram illustrating a configuration of a sensor module according to a second embodiment.

### DESCRIPTION OF EMBODIMENTS

Hereinafter, preferred embodiments of the present disclosure will be described in detail with reference to the drawings. The embodiments to be described below do not unduly limit contents of the present disclosure described in the claims. In addition, not all configurations to be described below are necessarily essential components of the present disclosure.

### 1. First Embodiment

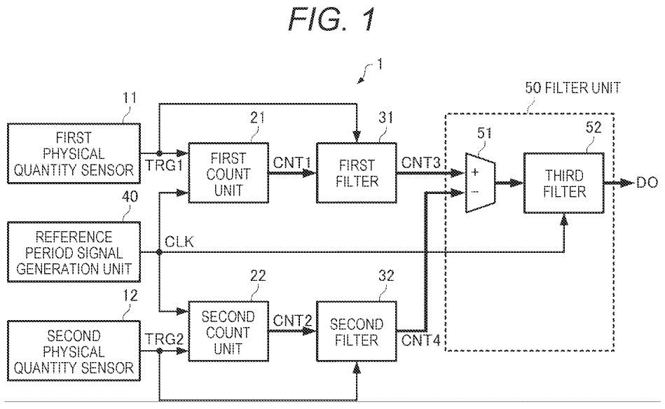

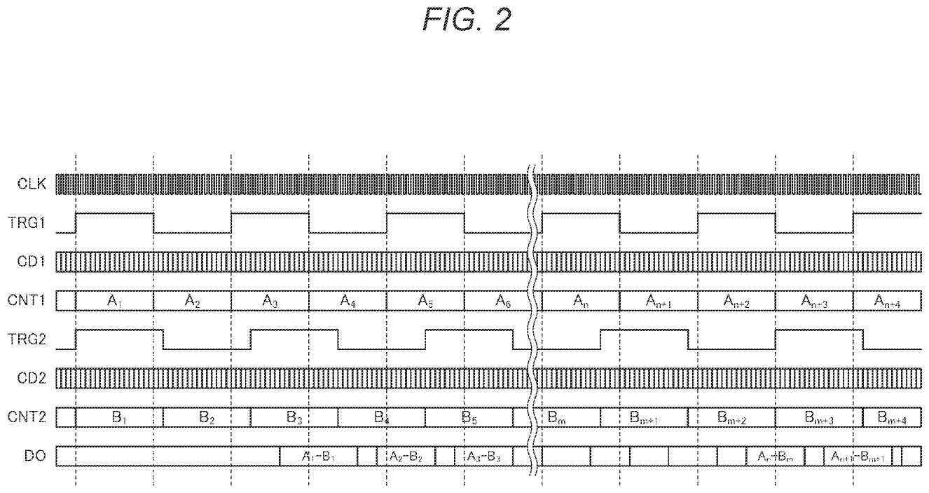

FIG. 1 is a block diagram illustrating a configuration of a sensor module according to a first embodiment. FIG. 2 is a timing chart diagram illustrating an example of an operation of the sensor module according to the first embodiment. A sensor module 1 according to the first embodiment is attached to an object to be measured (not illustrated) and outputs a measurement value DO corresponding to a detected physical quantity. As illustrated in FIG. 1, the sensor module 1 includes a first physical quantity sensor 11, a second physical quantity sensor 12, a first count unit 21, a second count unit 22, a first filter 31, a second filter 32, a reference period signal generation unit 40, and a filter unit 50.

The first physical quantity sensor 11 detects a physical quantity using a first axis as a detection axis, and outputs a first measured signal TRG1 whose frequency changes according to a magnitude of the detected physical quantity. Specifically, the first physical quantity sensor 11 includes a first physical quantity detection element (not illustrated) that detects the physical quantity using the first axis as the detection axis and a first oscillation circuit (not illustrated) that oscillates the first physical quantity detection element. The first oscillation circuit outputs the first measured signal TRG1.

The second physical quantity sensor 12 detects a physical quantity using a second axis as a detection axis, and outputs a second measured signal TRG2 whose frequency changes according to a magnitude of the detected physical quantity. Specifically, the second physical quantity sensor 12 includes a second physical quantity detection element (not illustrated) that detects the physical quantity using the second axis as the detection axis and a second oscillation circuit (not illustrated) that oscillates the second physical quantity detection element. The second oscillation circuit outputs the second measured signal TRG2.

The physical quantity detected by the first physical quantity sensor 11 is the same as the physical quantity detected by the second physical quantity sensor 12. For example, the physical quantity may be acceleration, angular velocity, angular acceleration, or pressure.

In the embodiment, the first physical quantity sensor 11 and the second physical quantity sensor 12 are attached in the sensor module 1 at positions close to each other such that the detection axes thereof are in opposite directions. Therefore, the second axis is opposite to the first axis. Here, the second axis being opposite to the first axis includes not only a case in which an angle formed by the first axis and the second axis is exactly 180°, but also a case in which the angle formed by the first axis and the second axis has an error with respect to 180° due to manufacturing errors, attachment errors, and the like of the first physical quantity sensor 11 and the second physical quantity sensor 12. Further, since an effect can be attained when the second axis is a detection axis having a sensitivity of a sign different from that of the first axis with respect to the physical quantity of a first axis component, “the second axis being opposite to the first axis” includes not only the case in which the angle formed by the first axis and the second axis is exactly 180° but also a case in which a direction component of the second axis includes an opposite direction component of the first axis.

In the first physical quantity sensor 11 and the second physical quantity sensor 12, since the detection axes thereof are opposite to each other, when a frequency f1 of the first measured signal TRG1 changes in a direction in which the frequency f1 increases, a frequency f2 of the second measured signal TRG2 changes in a direction in which the frequency f2 decreases. Further, when the frequency f1 of the first measured signal TRG1 changes in a direction in which the frequency f1 decreases, the frequency f2 of the second measured signal TRG2 changes in a direction in which the frequency f2 increases. In the following description, it is assumed that both the frequency f1 and the frequency f2 are a reference frequency f0 when the physical quantity is zero, the frequency f1 is higher than the reference frequency f0 by Δf and the frequency f2 is lower than the reference frequency f0 by Δf when a physical quantity in a direction of the first axis is generated, and the frequency f1 is lower than the reference frequency f0 by Δf and the frequency f2 is higher than the reference frequency f0 by Δf when a physical quantity in a direction of the second axis is generated.

The reference period signal generation unit 40 outputs a reference period signal CLK. For example, the reference period signal generation unit 40 may be an oscillation circuit that oscillates a crystal vibrator or a silicon MEMS resonator to output the reference period signal CLK, or may be an oscillation circuit that uses an SAW resonator. SAW is an abbreviation for surface acoustic wave. Alternatively, the reference period signal generation unit 40 may be an RC oscillation circuit or an LC oscillation circuit that outputs the reference period signal CLK.

The first count unit 21 counts, in synchronization with one of the first measured signal TRG1 and the reference period signal CLK, a time event of the other of the first measured signal TRG1 and the reference period signal CLK to generate a first count value CNT1.

The second count unit 22 counts, in synchronization with one of the second measured signal TRG2 and the reference period signal CLK, a time event of the other of the second measured signal TRG2 and the reference period signal CLK to generate a second count value CNT2.

A time event of the first measured signal TRG1 is a timing at which the first measured signal TRG1 changes, and may be, for example, a rising edge or a falling edge of the first measured signal TRG1 or the rising edge and the falling edge of the first measured signal TRG1. Similarly, a time event of the second measured signal TRG2 is a timing at which the second measured signal TRG2 changes, and may be, for example, a rising edge or a falling edge of the second measured signal TRG2 or the rising edge and the falling edge of the second measured signal TRG2. Similarly, a time event of the reference period signal CLK is a timing at which the reference period signal CLK changes, and may be, for example, a rising edge or a falling edge of the reference period signal CLK or the rising edge and the falling edge of the reference period signal CLK. In the example in FIG. 2, the first count unit 21 counts the rising edge of the reference period signal CLK in synchronization with the rising edge and the falling edge of the first measured signal TRG1 to generate the first count value CNT1. Similarly, the second count unit 22 counts the rising edge of the reference period signal CLK in synchronization with the rising edge and the falling edge of the second measured signal TRG2 to generate the second count value CNT2.

The first filter 31 receives the first count value CNT1, and performs filter processing for reducing a noise component included in the first count value CNT1 to output a third count value CNT3. The second filter 32 receives the second count value CNT2 and performs filter processing for reducing a noise component included in the second count value CNT2 to output a fourth count value CNT4. The first filter 31 operates in synchronization with the first measured signal TRG1, and the second filter 32 operates in synchronization with the second measured signal TRG2. The filter processing performed by the first filter 31 and the filter processing performed by the second filter 32 may be, for example, low-pass filter processing or band-pass filter processing.

The filter unit 50 outputs the measurement value DO based on a difference between the third count value CNT3 output from the first filter 31 and the fourth count value CNT4 output from the second filter 32.

In the embodiment, the filter unit 50 includes a subtractor 51 and a third filter 52. The subtractor 51 outputs a difference value between the third count value CNT3 output from the first filter 31 and the fourth count value CNT4 output from the second filter 32. The third filter 52 receives the difference value output from the subtractor 51 and performs filter processing on the difference value to output the measurement value DO. The third filter 52 operates in synchronization with the reference period signal CLK. The filter processing performed by the third filter 52 may be, for example, moving average processing, decimation processing, or the moving average processing and the decimation processing. The measurement value DO output from the third filter 52 is output from the sensor module 1 to an external device (not illustrated).

In the sensor module 1 implemented as described above, the first count value CNT1 indicates a frequency ratio of the first measured signal TRG1 and the reference period signal CLK, and the second count value CNT2 indicates a frequency ratio of the second measured signal TRG2 and the reference period signal CLK. As described above, when the physical quantity in the direction of the first axis is generated, the frequency f1 of the first measured signal TRG1 is higher than the reference frequency f0 by Δf, and the frequency f2 of the second measured signal TRG2 is lower than the reference frequency f0 by Δf. Therefore, the measurement value DO based on the difference between the first count value CNT1 and the second count value CNT2 is a value corresponding to 2Δf. When the physical quantity in the direction of the second axis is generated, the frequency f1 of the first measured signal TRG1 is lower than the reference frequency f0 by Δf, and the frequency f2 of the second measured signal TRG2 is higher than the reference frequency f0 by Δf. Therefore, the measurement value DO based on the difference between the first count value CNT1 and the second count value CNT2 is a value corresponding to −2Δf. In this way, the sensor module 1 functions as a frequency counter that measures a frequency change amount Δf of the first measured signal TRG1 with twice the sensitivity. In addition, the measurement value DO in which in-phase noise included in the first count value CNT1 and the second count value CNT2 is reduced is obtained based on the difference between the first count value CNT1 and the second count value CNT2. The external device can determine a magnitude of the physical quantity detected by the first physical quantity sensor 11 based on the measurement value DO and perform necessary calculation and control.

As is well known, a count method of the frequency counter includes a direct count method and a reciprocal count method. In the direct count method, the reference period signal CLK is used as an operation clock among the reference period signal CLK and the first measured signal TRG1 or the second measured signal TRG2. In the reciprocal count method, contrary to the direct count method, the first measured signal TRG1 or the second measured signal TRG2 is used as the operation clock.

Either the direct count method or the reciprocal count method may be used. In the following description, the sensor module 1 using the reciprocal count method will be taken as an example, and a specific configuration example of the first count unit 21 and the second count unit 22 will be described.

The first count unit 21 and the second count unit 22 are different in the received first measured signal TRG1 and the received second measured signal TRG2 and in the output first count value CNT1 and the output second count value CNT2, and have the same internal configuration. Therefore, the configuration of the first count unit 21 and the second count unit 22 will be described with the first measured signal TRG1 or the second measured signal TRG2 as a measured signal TRG and the first count value CNT1 or the second count value CNT2 as a count value CNT.

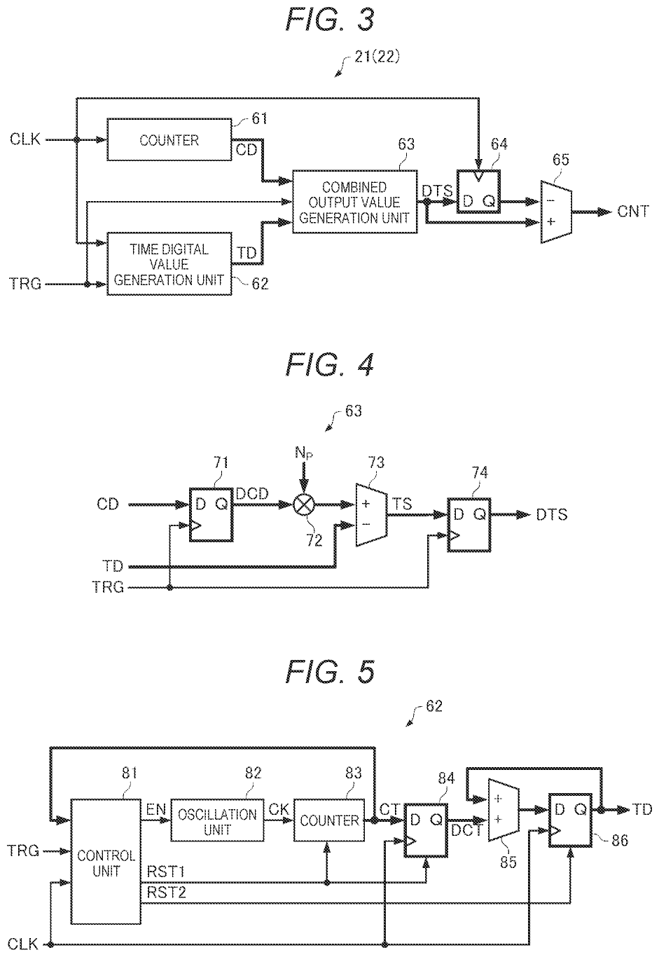

FIG. 3 is a diagram illustrating an example of the configuration of the first count unit 21 or the second count unit 22. As illustrated in FIG. 3, the first count unit 21 or the second count unit 22 includes a counter 61, a time digital value generation unit 62, a combined output value generation unit 63, a D flip-flop 64, and a subtractor 65. Although only one D flip-flop 64 is illustrated in FIG. 3 for simplification of illustration, there are actually N D flip-flops 64.

The counter 61 counts the number of edges of the reference period signal CLK. In the embodiment, the counter 61 counts the number of rising edges of the reference period signal CLK and outputs an M-bit count value CD.

The time digital value generation unit 62 generates an N-bit time digital value TD based on a phase difference between the measured signal TRG and the reference period signal CLK.

The combined output value generation unit 63 generates an N-bit combined output value DTS based on the time digital value TD and the count value CD. The combined output value generation unit 63 may generate the combined output value DTS in synchronization with the measured signal TRG. For example, the combined output value generation unit 63 may generate the combined output value DTS at either one of rising and falling timings of the measured signal TRG. Alternatively, the combined output value generation unit 63 may generate the combined output value DTS at both the rising and falling timings of the measured signal TRG. The combined output value DTS is a signal indicating a frequency ratio of the measured signal TRG and the reference period signal CLK.

The N D flip-flops 64 capture and store the N-bit combined output value DTS in synchronization with the reference period signal CLK. In the embodiment, when the rising edge of the reference period signal CLK arrives, the N D flip-flops 64 capture and hold the N-bit combined output value DTS.

The subtractor 65 subtracts the N-bit combined output value DTS stored by the N D flip-flops 64 from the N-bit combined output value DTS output from the combined output value generation unit 63, and outputs the N-bit count value CNT.

The combined output value generation unit 63 provided in the first count unit 21 and the combined output value generation unit 63 provided in the second count unit 22 are different in the received first measured signal TRG1 and the received second measured signal TRG2, and have the same internal configuration. Therefore, the configuration of the combined output value generation unit 63 will be described with the first measured signal TRG1 or the second measured signal TRG2 as the measured signal TRG.

FIG. 4 is a diagram illustrating an example of the configuration of the combined output value generation unit 63. As illustrated in FIG. 4, the combined output value generation unit 63 includes a D flip-flop 71, a multiplier 72, a subtractor 73, and a D flip-flop 74. Although only one D flip-flop 71 and one D flip-flop 74 are illustrated in FIG. 4 for simplification of illustration, there are actually M D flip-flops 71 and N D flip-flops 74.

The M D flip-flops 71 capture and store the M-bit count value CD in synchronization with the measured signal TRG. In the embodiment, the M D flip-flops 71 capture the M-bit count value CD in synchronization with a rising edge and a falling edge of the measured signal TRG and store the M-bit count value CD as an M-bit count value DCD. Specifically, the M D flip-flops 71 capture the count value CD when the rising edge of the measured signal TRG arrives, and store the count value CD as the count value DCD until the falling edge of the measured signal TRG arrives. Further, the M D flip-flops 71 capture the count value CD when the falling edge of the measured signal TRG arrives, and store the count value CD as the count value DCD until the rising edge of the measured signal TRG arrives.

The multiplier 72 multiplies the M-bit count value DCD by an integer Np. That is, the multiplier 72 outputs an N-bit value that is Np times the count value DCD. When the integer Np is an n-th power of 2, the multiplier 72 can be implemented as a simple circuit that shifts the count value DCD by n bits.

The subtractor 73 subtracts the N-bit time digital value TD output from the time digital value generation unit 62 from the N-bit value output from the multiplier 72 to output an N-bit time stamp value TS.

The N D flip-flops 74 capture and store the N-bit time stamp value TS in synchronization with the measured signal TRG. In the embodiment, when the rising edge or the falling edge of the measured signal TRG arrives, the N D flip-flops 74 capture the N-bit time stamp value TS and store the N-bit time stamp value TS as the N-bit combined output value DTS.

The time digital value generation unit 62 provided in the first count unit 21 and the time digital value generation unit 62 provided in the second count unit 22 are different in the received first measured signal TRG1 and the received second measured signal TRG2, and have the same internal configuration. Therefore, the configuration of the time digital value generation unit 62 will be described with the first measured signal TRG1 or the second measured signal TRG2 as the measured signal TRG.

FIG. 5 is a diagram illustrating an example of the configuration of the time digital value generation unit 62. As illustrated in FIG. 5, the time digital value generation unit 62 includes a control unit 81, an oscillation unit 82, a counter 83, a D flip-flop 84, an adder 85, and a D flip-flop 86. Although only one D flip-flop 84 and one D flip-flop 86 are illustrated in FIG. 5 for simplification of illustration, there are actually K D flip-flops 84 and N D flip-flops 86.

The control unit 81 detects the rising edge and the falling edge of the measured signal TRG, and activates and outputs an enable signal EN. In the embodiment, the enable signal EN is active at a high level. After the enable signal EN is set to the high level, the control unit 81 switches, based on a count value CT output from the counter 83, the enable signal EN from the high level to a low level when the number of rising edges of a clock signal CK output from the oscillation unit 82 reaches a predetermined number. Then, after the enable signal EN is switched from the high level to the low level, the control unit 81 activates and outputs a reset signal RST1 when the rising edge of the reference period signal CLK arrives a predetermined number of times. In the embodiment, the reset signal RST1 is active at a high level. The control unit 81 switches the reset signal RST1 from the high level to a low level when a predetermined time elapses after the reset signal RST1 is set to the high level. Then, after the enable signal EN is set to the high level, the control unit 81 activates and outputs a reset signal RST2 when a first rising edge of the reference period signal CLK arrives. In the embodiment, the reset signal RST2 is active at a high level. The control unit 81 switches the reset signal RST2 from the high level to a low level when a predetermined time elapses after the reset signal RST2 is set to the high level. The enable signal EN is supplied to the oscillation unit 82, the reset signal RST1 is supplied to the counter 83 and the K D flip-flops 84, and the reset signal RST2 is supplied to the N D flip-flops 86.

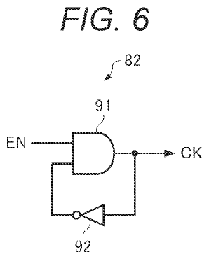

The oscillation unit 82 oscillates when the enable signal EN is at the high level, and stops oscillating when the enable signal EN is at the low level. For example, as illustrated in FIG. 6, the oscillation unit 82 includes a two-input AND circuit 91 and a logic inversion circuit 92. The AND circuit 91 receives the enable signal EN and an output signal of the logic inversion circuit 92, and outputs an AND signal of the enable signal EN and the output signal of the logic inversion circuit 92. The logic inversion circuit 92 receives an output signal of the AND circuit 91, and outputs a logic inversion signal of the output signal of the AND circuit 91.

The counter 83 counts the number of edges of the clock signal CK. In the embodiment, when the reset signal RST1 is at the low level, the counter 83 counts the number of rising edges of the clock signal CK and outputs the K-bit count value CT. When the reset signal RST1 is at the high level, the counter 83 initializes the count value CT to zero.

The K D flip-flops 84 capture and store the K-bit count value CT in synchronization with the reference period signal CLK. In the embodiment, when the reset signal RST1 is at the low level, when the rising edge of the reference period signal CLK arrives, the K D flip-flops 84 capture the K-bit count value CT and store the K-bit count value CT as a K-bit count value DCT. When the reset signal RST1 is at the high level, the K D flip-flops 84 initialize the count value DCT to zero.

The adder 85 adds an N-bit value stored and output by the N D flip-flops 86 and the K-bit count value DCT stored by the K D flip-flops 84 to output an N-bit addition value.

The N D flip-flops 86 capture and store the addition value output from the adder 85 in synchronization with the reference period signal CLK. In the embodiment, when the reset signal RST2 is at the low level, when the rising edge of the reference period signal CLK arrives, the N D flip-flops 86 capture the N-bit addition value output from the adder 85 and store the N-bit addition value as the N-bit time digital value TD. When the reset signal RST2 is at the high level, the N D flip-flops 86 initialize the time digital value TD to zero.

The time digital value generation unit 62 implemented as described above generates the time digital value TD by a ΣATDC method in which the count value DCT whose value increases in synchronization with the reference period signal CLK is integrated. ATDC is an abbreviation of accumulated time to digital convert.

In the first count unit 21 implemented as illustrated in FIGS. 3 to 6, the first count value CNT1 is a reciprocal count value, and is a value corresponding to a time from the rising edge to the next falling edge of the first measured signal TRG1 or a time from the falling edge to the next rising edge of the first measured signal TRG1. That is, the first count value CNT1 is a larger value as a time between two consecutive edges of the first measured signal TRG1 is longer and is a smaller value as a time between two consecutive edges of the first measured signal TRG1 is shorter. That is, the first count value CNT1 is a value corresponding to a cycle of the first measured signal TRG1.

Similarly, in the second count unit 22 implemented as illustrated in FIGS. 3 to 6, the second count value CNT2 is a reciprocal count value, and is a value corresponding to a time from the rising edge to the next falling edge of the second measured signal TRG2 or a time from the falling edge to the next rising edge of the second measured signal TRG2. That is, the second count value CNT2 is a larger value as a time between two consecutive edges of the second measured signal TRG2 is longer and is a smaller value as a time between two consecutive edges of the second measured signal TRG2 is shorter. That is, the second count value CNT2 is a value corresponding to a cycle of the second measured signal TRG2.

The time digital value generation unit 62 provided in the first count unit 21 is an example of a “first time digital value generation unit”, and the time digital value TD generated by the time digital value generation unit 62 is an example of a “first time digital value”. The combined output value generation unit 63 provided in the first count unit 21 is an example of a “first combined output value generation unit”, and the combined output value DTS generated by the combined output value generation unit 63 is an example of a “first combined output value”. The time digital value generation unit 62 provided in the second count unit 22 is an example of a “second time digital value generation unit”, and the time digital value TD generated by the time digital value generation unit 62 is an example of a “second time digital value”. Further, the combined output value generation unit 63 provided in the second count unit 22 is an example of a “second combined output value generation unit”, and the combined output value DTS generated by the combined output value generation unit 63 is an example of a “second combined output value”.

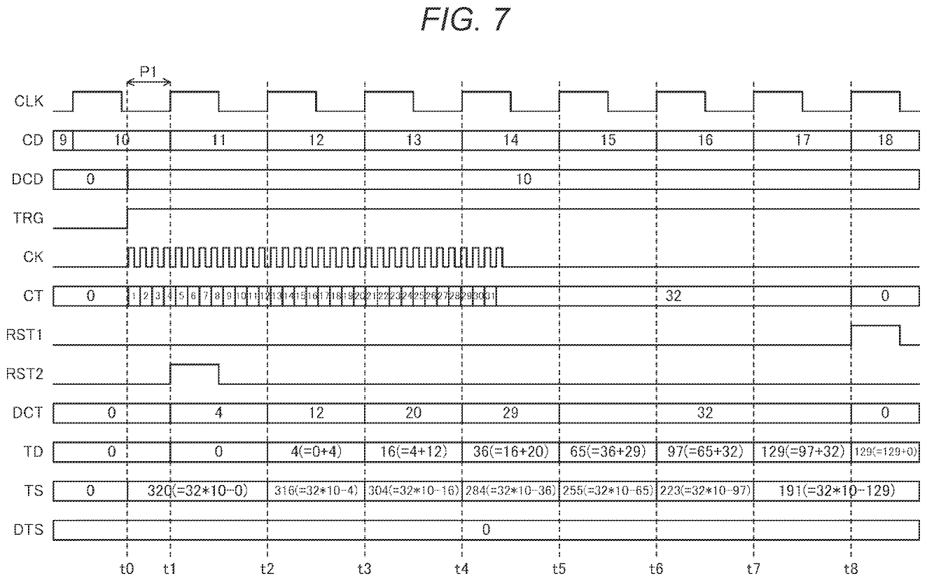

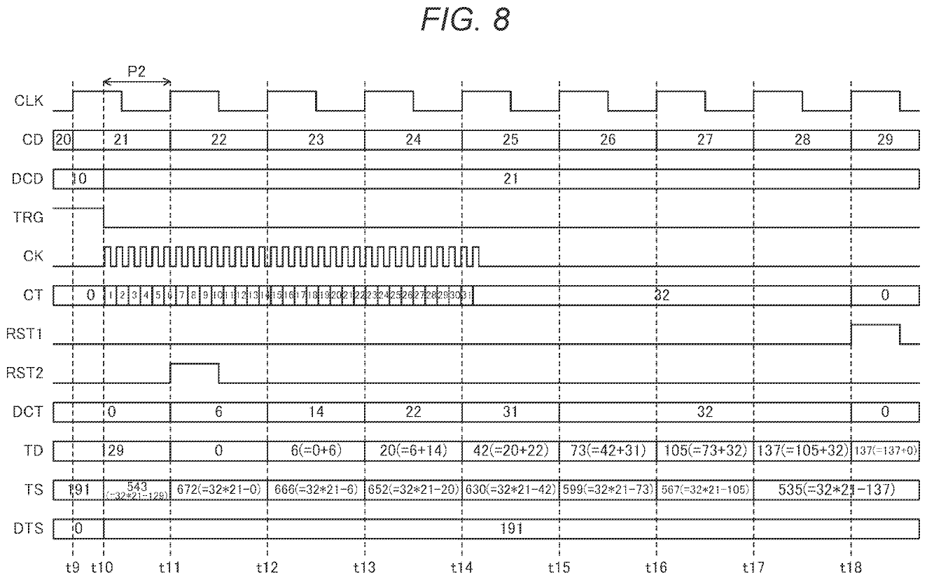

Next, detailed operations of the time digital value generation unit 62 and the combined output value generation unit 63 will be described with reference to FIGS. 7 and 8. FIGS. 7 and 8 are timing chart diagrams illustrating examples of the operations of the time digital value generation unit 62 and the combined output value generation unit 63. In the examples in FIGS. 7 and 8, the integer Np received by the multiplier 72 of the combined output value generation unit 63 is 32.

As illustrated in FIG. 7, each time the rising edge of the reference period signal CLK arrives, the count value CD increases by one. At a time point to, when the measured signal TRG transits from the low level to the high level, the count value CD at this time is 10, and therefore the count value DCD changes from 0 to 10, and the time stamp value TS changes from 0 to 320. Further, when the measured signal TRG transits from the low level to the high level, the oscillation unit 82 starts oscillating, and the count value CT increases by one each time the rising edge of the clock signal CK arrives.

At a time point t1 at which a time P1 has elapsed from the time point to, the first rising edge of the reference period signal CLK after the measured signal TRG transits to the high level arrives, and the count value DCT changes from 0 to 4 in synchronization with the edge. In synchronization with the edge, the reset signal RST2 transits from the low level to the high level, and the time digital value TD is initialized to zero. Then, the reset signal RST2 transits from the high level to the low level, and the initialization operation of the time digital value TD is released.

At a time point t2, a second rising edge of the reference period signal CLK arrives, and the count value DCT changes from 4 to 12 and the time digital value TD changes from 0 to 4 in synchronization with the edge. Further, the time stamp value TS changes from 320 to 316 in synchronization with the edge.

At a time point t3, a third rising edge of the reference period signal CLK arrives, and the count value DCT changes from 12 to 20 and the time digital value TD changes from 4 to 16 in synchronization with the edge. Further, the time stamp value TS changes from 316 to 304 in synchronization with the edge.

At a time point t4, a fourth rising edge of the reference period signal CLK arrives, and the count value DCT changes from 20 to 29 and the time digital value TD changes from 16 to 36 in synchronization with the edge. Further, the time stamp value TS changes from 304 to 284 in synchronization with the edge. Then, when the count value CT reaches 32, the oscillation unit 82 stops oscillating, and the count value CT is maintained at 32.

At a time point t5, a fifth rising edge of the reference period signal CLK arrives, and the count value DCT changes from 29 to 32 and the time digital value TD changes from 36 to 65 in synchronization with the edge. Further, the time stamp value TS changes from 284 to 255 in synchronization with the edge.

At a time point t6, a sixth rising edge of the reference period signal CLK arrives, and the time digital value TD changes from 65 to 97 and the time stamp value TS changes from 255 to 223 in synchronization with the edge. The count value DCT remains unchanged at 32.

At a time point t7, a seventh rising edge of the reference period signal CLK arrives, and the time digital value TD changes from 97 to 129 and the time stamp value TS changes from 223 to 191 in synchronization with the edge. The count value DCT remains unchanged at 32.

At a time point t8, an eighth rising edge of the reference period signal CLK arrives, and the reset signal RST1 transits from the low level to the high level and the count value CT and the count value DCT are initialized to zero in synchronization with the edge. Since the count value CT changes from 32 to 0, the time digital value TD remains unchanged at 129, and the time stamp value TS remains unchanged at 191. Then, the reset signal RST1 transits from the high level to the low level, and the initialization of the count value CT and the count value DCT is released.

Then, as time elapses, as illustrated in FIG. 8, at a time point t9, an eleventh rising edge of the reference period signal CLK arrives, and the count value CD changes from 20 to 21. Then, at a time point t10, when the measured signal TRG transits from the high level to the low level, the time stamp value TS at this time is 191, and therefore the combined output value DTS changes from 0 to 191. Since the count value CD is 21 when the measured signal TRG transits from the high level to the low level, the count value DCD changes from 10 to 21, and the time stamp value TS changes from 191 to 543. Further, when the measured signal TRG transits from the high level to the low level, the oscillation unit 82 starts oscillating, and the count value CT increases by one each time the rising edge of the clock signal CK arrives.

At a time point t11 at which a time P2 elapses from the time point t10, a twelfth rising edge of the reference period signal CLK arrives, and the count value DCT changes from 0 to 6 in synchronization with the edge. In synchronization with the edge, the reset signal RST2 transits from the low level to the high level, the time digital value TD is initialized to zero, and the time stamp value TS changes from 543 to 672. Then, the reset signal RST2 transits from the high level to the low level, and the initialization operation of the time digital value TD is released.

At a time point t12, a thirteenth rising edge of the reference period signal CLK arrives, and the count value DCT changes from 6 to 14 and the time digital value TD changes from 0 to 6 in synchronization with the edge. Further, the time stamp value TS changes from 672 to 666 in synchronization with the edge.

At a time point t13, a fourteenth rising edge of the reference period signal CLK arrives, and the count value DCT changes from 14 to 22 and the time digital value TD changes from 6 to 20 in synchronization with the edge. Further, the time stamp value TS changes from 666 to 652 in synchronization with the edge.

At a time point t14, a fifteenth rising edge of the reference period signal CLK arrives, and the count value DCT changes from 22 to 31 and the time digital value TD changes from 20 to 42 in synchronization with the edge. Further, the time stamp value TS changes from 652 to 630 in synchronization with the edge. Then, when the count value CT reaches 32, the oscillation unit 82 stops oscillating, and the count value CT is maintained at 32.

At a time point t15, a sixteenth rising edge of the reference period signal CLK arrives, and the count value DCT changes from 31 to 32 and the time digital value TD changes from 42 to 73 in synchronization with the edge. Further, the time stamp value TS changes from 630 to 599 in synchronization with the edge.

At a time point t16, a seventeenth rising edge of the reference period signal CLK arrives, and the time digital value TD changes from 73 to 105 and the time stamp value TS changes from 599 to 567 in synchronization with the edge. The count value DCT remains unchanged at 32.

At a time point t17, an eighteenth rising edge of the reference period signal CLK arrives, and the time digital value TD changes from 105 to 137 and the time stamp value TS changes from 567 to 535 in synchronization with the edge. The count value DCT remains unchanged at 32.

At a time point t18, a nineteenth rising edge of the reference period signal CLK arrives, and the reset signal RST1 transits from the low level to the high level and the count value CT and the count value DCT are initialized to zero in synchronization with the edge. Since the count value CT changes from 32 to 0, the time digital value TD remains unchanged at 137, and the time stamp value TS remains unchanged at 535. Then, the reset signal RST1 transits from the high level to the low level, and the initialization of the count value CT and the count value DCT is released.

The time P2 from the time point t10 to the time point t11 illustrated in FIG. 8 is longer than the time P1 from the time point t0 to the time point t1 illustrated in FIG. 7. The time digital value TD changes such that the time digital value TD at each time point from the time point t12 to the time point t18 is larger than the time digital value TD at each time point from the time point t2 to the time point t8. Therefore, the longer the time interval between the edge of the measured signal TRG and the rising edge of the reference period signal CLK is, the larger the time digital value TD is. Further, 129, which is the time digital value TD after changing at the time point t7, corresponds to the time P1, and 137, which is the time digital value TD after changing at the time point t17, corresponds to the time P2.

In the examples in FIGS. 7 and 8, when a time of one cycle of the reference period signal CLK is T, a time during which the measured signal TRG is at the high level is T×(21−10)+P1−P2=(T×21−P2)−(T×10−P1). Here, the time stamp value TS after changing at the time point t7, that is, 191 (=32×10−129) corresponds to (T×10−P1). Further, the time stamp value TS after changing at the time point t17, that is, 535 (=32×21−137) corresponds to (T×21−P2). Therefore, a difference value between the two combined output values DTS obtained by holding the two time stamp values TS at the edges of the measured signal TRG, that is, 344 (=535-191) corresponds to the time during which the measured signal TRG is at the high level, that is, a time interval between the rising edge and the falling edge of the measured signal TRG.

As a generalization, the count value CNT, which is a difference value between an i-th combined output value DTS and an (i+1)-th combined output value DTS, corresponds to a time interval between an i-th edge and an (i+1)-th edge of the measured signal TRG, that is, a half-cycle time of the measured signal TRG. Specifically, the first count value CNT1 corresponds to a half-cycle time of the first measured signal TRG1, and the second count value CNT2 corresponds to a half-cycle time of the second measured signal TRG2. Therefore, the measurement value DO corresponds to a difference between the half-cycle time of the first measured signal TRG1 and the half-cycle time of the second measured signal TRG2, and corresponds to a change amount of the frequency f1 of the first measured signal TRG1 from the reference frequency f0 as described above. Therefore, the external device can calculate the frequency of the first measured signal TRG1 based on the measurement value DO and measure the physical quantity detected by the first physical quantity sensor 11.

Here, as illustrated in FIGS. 7 and 8, in a period in which a plurality of the combined output values DTS are generated sequentially, the count value CD increases by 1 each time the rising edge of the reference period signal CLK arrives without stopping the reference period signal CLK. Accordingly, a quantization error of the combined output value DTS is fed back to the generation of the next combined output value DTS. That is, since the plurality of generated combined output values DTS satisfy a characteristic of a delta-sigma modulated signal, a noise shaping effect is attained, and the quantization error is shifted to a high-frequency band. Therefore, the external device can measure the physical quantity based on the measurement value DO with high accuracy.

As described above, in the sensor module 1 according to the first embodiment, the measurement value DO in which in-phase noise included in the third count value CNT3 and the fourth count value CNT4 is reduced is obtained according to a difference between the third count value CNT3 based on the first measured signal TRG1 output from the first physical quantity sensor 11 and the fourth count value CNT4 based on the second measured signal TRG2 output from the second physical quantity sensor 12. In addition, since the detection axis of the first physical quantity sensor 11 and the detection axis of the second physical quantity sensor 12 are opposite to each other, the measurement value DO with a higher sensitivity is obtained according to the difference between the third count value CNT3 based on the first measured signal TRG1 and the fourth count value CNT4 based on the second measured signal TRG2. Therefore, according to the sensor module 1 in the first embodiment, a measurement sensitivity can be improved while reducing the in-phase noise.

In the sensor module 1 according to the first embodiment, noise included in the first count value CNT1 based on the first measured signal TRG1 output from the first physical quantity sensor 11 is reduced by the first filter 31, and noise included in the second count value CNT2 based on the second measured signal TRG2 output from the second physical quantity sensor 12 is reduced by the second filter 32. That is, according to the sensor module 1 in the first embodiment, the noise that is not in-phase included in the first count value CNT1 and the second count value CNT2 can be individually reduced by the first filter 31 and the second filter 32.

The sensor module 1 according to the first embodiment generates the first count value CNT1 which is a digital value without performing analog signal processing on the first measured signal TRG1 output from the first physical quantity sensor 11, and generates the second count value CNT2 which is a digital value without performing analog signal processing on the second measured signal TRG2 output from the second physical quantity sensor 12. Therefore, according to the sensor module 1 in the first embodiment, even when the first measured signal TRG1 and the second measured signal TRG2 have a frequency component caused by high-frequency electromagnetic vibration noise generated in a measurement target object and a harmonic component thereof, since there is no need to provide an analog circuit that is likely to be affected by high-frequency noise, the first measured signal TRG1 and the second measured signal TRG2 are less likely to be affected by the high-frequency electromagnetic vibration noise. According to the sensor module 1 in the first embodiment, since there is no need to remove the frequency component caused by the high-frequency electromagnetic vibration noise and the harmonic component thereof from the first measured signal TRG1 and the second measured signal TRG2, a circuit scale is reduced.

According to the sensor module 1 in the first embodiment, in the filter unit 50, various types of signal processing can be performed on the third count value CNT3 based on the first measured signal TRG1 and the fourth count value CNT4 based on the second measured signal TRG2.

In the sensor module 1 according to the first embodiment, since the quantization error of the combined output value DTS is fed back to the generation of the next combined output value DTS in the first count unit 21, the combined output value DTS satisfies the characteristic of the delta-sigma modulated signal, the noise shaping effect is attained, and the quantization error is shifted to the high-frequency band. Similarly, since the quantization error of the combined output value DTS is fed back to the generation of the next combined output value DTS in the second count unit 22, the combined output value DTS satisfies the characteristic of the delta-sigma modulated signal, the noise shaping effect is attained, and the quantization error is shifted to the high-frequency band. Therefore, according to the sensor module 1 in the first embodiment, an S/N ratio of the time digital value TD generated based on the combined output value DTS in the first count unit 21 and the time digital value TD generated based on the combined output value DTS in the second count unit 22 is improved.

Generally, there is a difference in measurement accuracy between the direct count method and the reciprocal count method, so it is necessary to select an optimal count method depending on a correlation between a frequency band of the measured signal TRG and a frequency of the reference period signal CLK. In contrast, according to the sensor module 1 in the first embodiment, in the first count unit 21 and the second count unit 22, since the combined output value DTS satisfies the characteristic of the delta-sigma modulated signal, the same measurement accuracy can be implemented with either method. Therefore, the count method can be selected without considering measurement accuracy constraints. For example, the first count unit 21 may count a time event of a signal having a shorter cycle in synchronization with a signal having a longer cycle from the first measured signal TRG1 and the reference period signal CLK, and the second count unit 22 may count a time event of a signal having a shorter cycle in synchronization with a signal having a longer cycle from the second measured signal TRG2 and the reference period signal CLK. Accordingly, it is possible to lower an operation frequency than that in a configuration in which a time event of a signal having a longer cycle is counted in synchronization with a signal having a shorter cycle from the first measured signal TRG1 and the reference period signal CLK and a time event of a signal having a longer cycle is counted in synchronization with a signal having a shorter cycle from the second measured signal TRG2 and the reference period signal CLK. Therefore, it is possible to reduce power consumption while maintaining the measurement accuracy.

According to the sensor module 1 in the first embodiment, since the filter for the third count value CNT3 and the fourth count value CNT4 can be unified in the filter unit 50, an increase in necessary circuit resources can be prevented.

Further, in the sensor module 1 according to the first embodiment, the first filter 31 operates in synchronization with the first measured signal TRG1, and the third filter 52 provided at a subsequent stage of the first filter 31 operates in synchronization with the reference period signal CLK different from the first measured signal TRG1. Accordingly, nonlinearity occurs in a correlation between the first count value CNT1 received by the first filter 31 and the measurement value DO output from the third filter 52. Similarly, the second filter 32 operates in synchronization with the second measured signal TRG2, and the third filter 52 provided at a subsequent stage of the second filter 32 operates in synchronization with the reference period signal CLK different from the second measured signal TRG2. Accordingly, nonlinearity occurs in a correlation between the second count value CNT2 received by the second filter 32 and the measurement value DO output from the third filter 52. A vibration rectification error caused by the nonlinearity changes according to a group delay amount of each of the first filter 31, the second filter 32, and the third filter 52. Therefore, according to the sensor module 1 in the first embodiment, by setting the group delay amount of each of the first filter 31, the second filter 32, and the third filter 52 to an appropriate value, the vibration rectification error caused by the nonlinearity and a vibration rectification error caused by asymmetry of the first measured signal TRG1 and asymmetry of the second measured signal TRG2 cancel each other out, and the vibration rectification error included in the measurement value DO is reduced.

### 2. Second Embodiment

Hereinafter, regarding the sensor module 1 according to a second embodiment, the same components as those in the first embodiment are denoted by the same reference signs, description overlapping with that of the first embodiment is omitted or simplified, and contents different from those of the first embodiment will be mainly described.

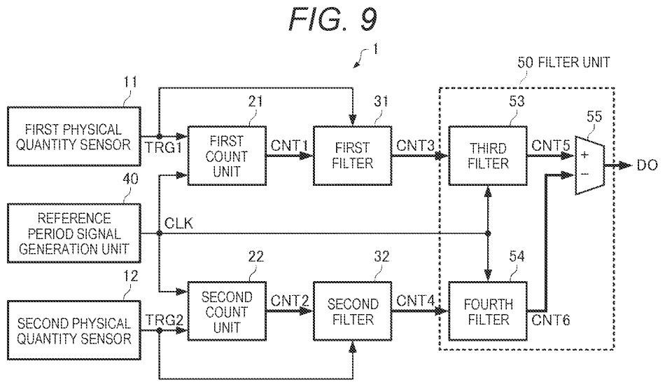

FIG. 9 is a block diagram illustrating a configuration of the sensor module 1 according to the second embodiment. In FIG. 9, the same components as those in FIG. 1 are denoted by the same reference signs. As illustrated in FIG. 9, the sensor module 1 according to the second embodiment includes the first physical quantity sensor 11, the second physical quantity sensor 12, the first count unit 21, the second count unit 22, the first filter 31, the second filter 32, the reference period signal generation unit 40, and the filter unit 50. Since configurations and functions of the first physical quantity sensor 11, the second physical quantity sensor 12, the first count unit 21, the second count unit 22, the first filter 31, the second filter 32, and the reference period signal generation unit 40 are the same as those in the first embodiment, description thereof will be omitted.

As in the first embodiment, the filter unit 50 outputs the measurement value DO based on a difference between the third count value CNT3 output from the first filter 31 and the fourth count value CNT4 output from the second filter 32. However, a configuration of the filter unit 50 is different from that in the first embodiment. As illustrated in FIG. 9, the filter unit 50 includes a third filter 53, a fourth filter 54, and a subtractor 55.

The third filter 53 receives the third count value CNT3 output from the first filter 31, performs filter processing on the third count value CNT3, and outputs a fifth count value CNT5. The third filter 53 operates in synchronization with the reference period signal CLK. The filter processing performed by the third filter 53 may be, for example, moving average processing, decimation processing, or the moving average processing and the decimation processing.

The fourth filter 54 receives the fourth count value CNT4 output from the second filter 32, performs filter processing on the fourth count value CNT4, and outputs a sixth count value CNT6. The fourth filter 54 operates in synchronization with the reference period signal CLK. The filter processing performed by the fourth filter 54 may be, for example, moving average processing, decimation processing, or the moving average processing and the decimation processing.

The subtractor 55 outputs a difference value between the fifth count value CNT5 output from the third filter 53 and the sixth count value CNT6 output from the fourth filter 54 as the measurement value DO. The measurement value DO output from the subtractor 55 is output from the sensor module 1 to an external device (not illustrated).

Other configurations and functions of the sensor module 1 according to the second embodiment are the same as those of the first embodiment, and therefore description thereof will be omitted.

According to the sensor module 1 in the second embodiment described above, the same effects as those of the sensor module 1 according to the first embodiment can be attained.

According to the sensor module 1 in the second embodiment, even when a characteristic of the first physical quantity sensor 11 and a characteristic of the second physical quantity sensor 12 are different from each other, in the filter unit 50, the characteristic of the first physical quantity sensor 11 can be compensated by the third filter 53, and the characteristic of the second physical quantity sensor 12 can be compensated by the fourth filter 54. For example, when a structural resonance frequency of the first physical quantity sensor 11 is different from a structural resonance frequency of the second physical quantity sensor 12, a frequency characteristic of the first physical quantity sensor 11 can be compensated by the third filter 53, and a frequency characteristic of the second physical quantity sensor 12 can be compensated by the fourth filter 54. For example, a designer can individually design an FIR filter as the third filter 53 that compensates a gain characteristic and a phase characteristic of the first physical quantity sensor 11 and an FIR filter as the fourth filter 54 that compensates a gain characteristic and a phase characteristic of the second physical quantity sensor 12. FIR is an abbreviation for finite impulse response.

Further, in the sensor module 1 according to the second embodiment, the first filter 31 operates in synchronization with the first measured signal TRG1, and the third filter 53 provided at a subsequent stage of the first filter 31 operates in synchronization with the reference period signal CLK different from the first measured signal TRG1. Accordingly, nonlinearity occurs in a correlation between the first count value CNT1 received by the first filter 31 and the fifth count value CNT5 output from the third filter 53. Similarly, the second filter 32 operates in synchronization with the second measured signal TRG2, and the fourth filter 54 provided at a subsequent stage of the second filter 32 operates in synchronization with the reference period signal CLK different from the second measured signal TRG2. Accordingly, nonlinearity occurs in a correlation between the second count value CNT2 received by the second filter 32 and the sixth count value CNT6 output from the fourth filter 54. A vibration rectification error caused by the nonlinearity changes according to a group delay amount of each of the first filter 31, the second filter 32, the third filter 53, and the fourth filter 54. Therefore, according to the sensor module 1 in the second embodiment, by setting the group delay amount of each of the first filter 31, the second filter 32, the third filter 53, and the fourth filter 54 to an appropriate value, the vibration rectification error caused by the nonlinearity and a vibration rectification error caused by asymmetry of the first measured signal TRG1 and asymmetry of the second measured signal TRG2 cancel each other out, and the vibration rectification error included in the measurement value DO, which is the difference value between the fifth count value CNT5 and the sixth count value CNT6, is reduced.

### 3. Modifications

In the embodiments described above, the combined output value generation unit 63 generates the combined output value DTS in synchronization with both a rising edge and a falling edge of the measured signal TRG. In this case, the measurement value DO corresponds to a half-cycle time of the first measured signal TRG1. In contrast, the combined output value generation unit 63 may generate the combined output value DTS in synchronization with only one of the rising edge and the falling edge of the measured signal TRG. In this case, the measurement value DO corresponds to a one-cycle time of the first measured signal TRG1.

In the embodiments described above, a reciprocal count method in which the reference period signal CLK is used as an operation clock is described as an example of a count method of the first count unit 21. The count method of the first count unit 21 may be a direct count method in which the first measured signal TRG1 is used as the operation clock. Similarly, in the embodiments described above, a reciprocal count method in which the reference period signal CLK is used as an operation clock is described as an example of a count method of the second count unit 22. The count method of the second count unit 22 may be a direct count method in which the second measured signal TRG2 is used as the operation clock.

Although the embodiments and the modifications are described above, the present disclosure is not limited to the embodiments and can be implemented in various modes without departing from the gist thereof. For example, the embodiments described above can be appropriately combined.

The present disclosure has substantially the same configurations as the configurations described in the embodiments, such as a configuration having the same function, method, and result and a configuration having the same object and effect. The present disclosure has a configuration in which a non-essential portion of the configuration described in the embodiments is replaced. The present disclosure may have a configuration capable of achieving the same function and effect or a configuration capable of achieving the same object as the configuration described in the embodiments. Further, the present disclosure has a configuration obtained by adding a known technique to the configuration described in the embodiments.

The following contents are derived from the embodiments and modifications described above.

A sensor module according to an aspect including:
a first physical quantity sensor configured to detect a physical quantity using a first axis as a detection axis and output a first measured signal whose frequency changes according to a magnitude of the physical quantity;
a second physical quantity sensor configured to detect a physical quantity using a second axis in a direction opposite to the first axis as a detection axis and output a second measured signal whose frequency changes according to a magnitude of the physical quantity;
a reference period signal generation unit configured to output a reference period signal;
a first count unit configured to count, in synchronization with one of the first measured signal and the reference period signal, a time event of the other of the first measured signal and the reference period signal to generate a first count value;
a second count unit configured to count, in synchronization with one of the second measured signal and the reference period signal, a time event of the other of the second measured signal and the reference period signal to generate a second count value;
a first filter configured to receive the first count value and output a third count value;
a second filter configured to receive the second count value and output a fourth count value; and
a filter unit configured to output a measurement value based on a difference between the third count value and the fourth count value.

In the sensor module, a measurement value in which in-phase noise included in the third count value and the fourth count value is reduced is obtained according to the difference between the third count value based on the first measured signal output from the first physical quantity sensor and the fourth count value based on the second measured signal output from the second physical quantity sensor. In addition, since the detection axis of the first physical quantity sensor and the detection axis of the second physical quantity sensor are opposite to each other, the measurement value with a higher sensitivity is obtained according to the difference between the third count value based on the first measured signal and the fourth count value based on the second measured signal. Therefore, according to the sensor module, a measurement sensitivity can be improved while reducing the in-phase noise.

In the sensor module, noise included in the first count value based on the first measured signal output from the first physical quantity sensor is reduced by the first filter, and noise included in the second count value based on the second measured signal output from the second physical quantity sensor is reduced by the second filter. That is, according to the sensor module, noise that is not in-phase included in the first count value and the second count value can be individually reduced by the first filter and the second filter.

The sensor module generates the first count value which is a digital value without performing analog signal processing on the first measured signal output from the first physical quantity sensor, and generates the second count value which is a digital value without performing analog signal processing on the second measured signal output from the second physical quantity sensor. Therefore, according to the sensor module, even when the first measured signal and the second measured signal have a frequency component caused by high-frequency electromagnetic vibration noise generated in a measurement target object and a harmonic component thereof, since there is no need to provide an analog circuit that is likely to be affected by high-frequency noise, the first measured signal and the second measured signal are less likely to be affected by the high-frequency electromagnetic vibration noise. According to the sensor module, since there is no need to remove the frequency component caused by the high-frequency electromagnetic vibration noise and the harmonic component thereof from the first measured signal and the second measured signal, a circuit scale is reduced.

According to the sensor module, in the filter unit, various types of signal processing can be performed on the third count value based on the first measured signal and the fourth count value based on the second measured signal.

In an aspect of the sensor module,
the filter unit may include
   a subtractor configured to output a difference value between the third count value and the fourth count value, and
   a third filter configured to receive the difference value and output the measurement value.

According to the sensor module, since the filter for the third count value and the fourth count value can be unified in the filter unit, an increase in necessary circuit resources can be prevented.

In an aspect of the sensor module,
the first filter may operate in synchronization with the first measured signal,
the second filter may operate in synchronization with the second measured signal, and
the third filter may operate in synchronization with the reference period signal.

In the sensor module, the first filter operates in synchronization with the first measured signal and the third filter provided at a subsequent stage of the first filter operates in synchronization with the reference period signal different from the first measured signal. Accordingly, nonlinearity occurs in a correlation between the first count value received by the first filter and the measurement value output from the third filter. Similarly, the second filter operates in synchronization with the second measured signal, and the third filter provided at a subsequent stage of the second filter operates in synchronization with the reference period signal different from the second measured signal. Accordingly, nonlinearity occurs in a correlation between the second count value received by the second filter and the measurement value output from the third filter. A vibration rectification error caused by the nonlinearity changes according to a group delay amount of each of the first filter, the second filter, and the third filter. Therefore, according to the sensor module, by setting the group delay amount of each of the first filter, the second filter, and the third filter to an appropriate value, the vibration rectification error caused by the nonlinearity and a vibration rectification error caused by asymmetry of the first measured signal and asymmetry of the second measured signal cancel each other out, and the vibration rectification error included in the measurement value is reduced.

In an aspect of the sensor module,
the filter unit may include
   a third filter configured to receive the third count value and output a fifth count value,
   a fourth filter configured to receive the fourth count value and output a sixth count value, and
   a subtractor configured to output a difference value between the fifth count value and the sixth count value as the measurement value.

According to the sensor module, even when a characteristic of the first physical quantity sensor and a characteristic of the second physical quantity sensor are different from each other, in the filter unit, the characteristic of the first physical quantity sensor can be compensated by the third filter, and the characteristic of the second physical quantity sensor can be compensated by the fourth filter. For example, when a structural resonance frequency of the first physical quantity sensor is different from a structural resonance frequency of the second physical quantity sensor, a frequency characteristic of the first physical quantity sensor can be compensated by the third filter, and a frequency characteristic of the second physical quantity sensor can be compensated by the fourth filter. For example, a designer can individually design an FIR filter as the third filter that compensates a gain characteristic and a phase characteristic of the first physical quantity sensor and an FIR filter as the fourth filter that compensates a gain characteristic and a phase characteristic of the second physical quantity sensor.

In an aspect of the sensor module,
the first filter may operate in synchronization with the first measured signal,
the second filter may operate in synchronization with the second measured signal, and
the third filter and the fourth filter may operate in synchronization with the reference period signal.

In the sensor module, the first filter operates in synchronization with the first measured signal, and the third filter provided at the subsequent stage of the first filter operates in synchronization with the reference period signal different from the first measured signal. Accordingly, nonlinearity occurs in a correlation between the first count value received by the first filter and the fifth count value output from the third filter. Similarly, the second filter operates in synchronization with the second measured signal, and the fourth filter provided at the subsequent stage of the second filter operates in synchronization with the reference period signal different from the second measured signal. Accordingly, nonlinearity occurs in a correlation between the second count value received by the second filter and the sixth count value output from the fourth filter. A vibration rectification error caused by the nonlinearity changes according to a group delay amount of each of the first filter, the second filter, the third filter, and the fourth filter. Therefore, according to the sensor module, by setting the group delay amount of each of the first filter, the second filter, the third filter, and the fourth filter to an appropriate value, the vibration rectification error caused by the nonlinearity and a vibration rectification error caused by asymmetry of the first measured signal and asymmetry of the second measured signal cancel each other out, and the vibration rectification error included in the measurement value, which is the difference value between the fifth count value and the sixth count value, is reduced.

In an aspect of the sensor module,
the first count unit may include
   a first time digital value generation unit configured to generate a first time digital value based on a phase difference between the first measured signal and the reference period signal, and
   a first combined output value generation unit configured to generate a first combined output value based on the first time digital value and the first count value,
a quantization error of the first combined output value may be fed back to generation of the next first combined output value,
the second count unit may include
   a second time digital value generation unit configured to generate a second time digital value based on a phase difference between the second measured signal and the reference period signal, and
   a second combined output value generation unit configured to generate a second combined output value based on the second time digital value and the second count value, and
a quantization error of the second combined output value may be fed back to generation of the next second combined output value.

In the sensor module, since the quantization error of the first combined output value is fed back to the generation of the next first combined output value, the first combined output value satisfies a characteristic of a delta-sigma modulated signal, a noise shaping effect is attained, and the quantization error is shifted to the high-frequency band. Similarly, since the quantization error of the second combined output value is fed back to the generation of the next second combined output value, the second combined output value satisfies the characteristic of the delta-sigma modulated signal, the noise shaping effect is attained, and the quantization error is shifted to the high-frequency band. Therefore, according to the sensor module, an S/N ratio of the first time digital value generated based on the first combined output value and the second time digital value generated based on the second combined output value is improved.

Generally, there is a difference in measurement accuracy between the direct count method and the reciprocal count method, so it is necessary to select an optimal count method depending on a correlation between a frequency band of the measured signal and a frequency of the reference period signal. In contrast, according to the sensor module, since the first combined output value and the second combined output value satisfy the characteristic of the delta-sigma modulated signal, the same measurement accuracy can be attained with either method. Therefore, the count method can be selected without considering measurement accuracy constraints. For example, the first count unit may count a time event of a signal having a shorter cycle in synchronization with a signal having a longer cycle from the first measured signal and the reference period signal, and the second count unit may count a time event of a signal having a shorter cycle in synchronization with a signal having a longer cycle from the second measured signal and the reference period signal. Accordingly, it is possible to lower an operation frequency than that in a configuration in which a time event of a signal having a longer cycle is counted in synchronization with a signal having a shorter cycle from the first measured signal and the reference period signal and a time event of a signal having a longer cycle is counted in synchronization with a signal having a shorter cycle from the second measured signal and the reference period signal. Therefore, it is possible to reduce power consumption while maintaining the measurement accuracy.

What is claimed is:

1. A sensor module comprising:
a first physical quantity sensor configured to detect a physical quantity using a first axis as a detection axis and output a first measured signal whose frequency changes according to a magnitude of the physical quantity;
a second physical quantity sensor configured to detect a physical quantity using a second axis in a direction opposite to the first axis as a detection axis and output a second measured signal whose frequency changes according to a magnitude of the physical quantity;
a reference period signal generation unit configured to output a reference period signal;
a first count unit configured to count, in synchronization with one of the first measured signal and the reference period signal, a time event of the other of the first measured signal and the reference period signal to generate a first count value;
a second count unit configured to count, in synchronization with one of the second measured signal and the reference period signal, a time event of the other of the second measured signal and the reference period signal to generate a second count value;
a first filter configured to receive the first count value and output a third count value;
a second filter configured to receive the second count value and output a fourth count value; and
a filter unit configured to output a measurement value based on a difference between the third count value and the fourth count value.

2. The sensor module according to claim 1, wherein
the filter unit includes
a subtractor configured to output a difference value between the third count value and the fourth count value, and
a third filter configured to receive the difference value and output the measurement value.

3. The sensor module according to claim 2, wherein
the first filter operates in synchronization with the first measured signal,
the second filter operates in synchronization with the second measured signal, and
the third filter operates in synchronization with the reference period signal.

4. The sensor module according to claim 1, wherein
the filter unit includes
a third filter configured to receive the third count value and output a fifth count value,
a fourth filter configured to receive the fourth count value and output a sixth count value, and
a subtractor configured to output a difference value between the fifth count value and the sixth count value as the measurement value.

5. The sensor module according to claim 4, wherein
the first filter operates in synchronization with the first measured signal,
the second filter operates in synchronization with the second measured signal, and
the third filter and the fourth filter operate in synchronization with the reference period signal.

6. The sensor module according to claim 1, wherein
the first count unit includes
a first time digital value generation unit configured to generate a first time digital value based on a phase difference between the first measured signal and the reference period signal, and
a first combined output value generation unit configured to generate a first combined output value based on the first time digital value and the first count value,
a quantization error of the first combined output value is fed back to generation of the next first combined output value,
the second count unit includes
a second time digital value generation unit configured to generate a second time digital value based on a phase difference between the second measured signal and the reference period signal, and
a second combined output value generation unit configured to generate a second combined output value based on the second time digital value and the second count value, and
a quantization error of the second combined output value is fed back to generation of the next second combined output value.
